(19) United States
(12) Patent Application Publication
(10) Pub. No.: US 2016/0212883 A1
(43) Pub. Date: Jul. 21, 2016

(54) SUBSEA ENCLOSURE SYSTEM FOR DISPOSAL OF GENERATED HEAT

(71) Applicant: SIEMENS AKTIENGESELLSCHAFT, München (DE)

(72) Inventors: Knut Schonhowd KRISTENSEN, Trondheim (NO); Baard Jonas WIGESTRAND, Trondheim (NO)

(21) Appl. No.: 14/914,114

(22) PCT Filed: Sep. 18, 2014
(86) PCT No.: PCT/EP2014/069870

§ 371 Date: Feb. 24, 2016

(30) Foreign Application Priority Data
Sep. 25, 2013 (EP) 13185892.0

(51) Int. Cl. H05K 7/20; E21B 41/00

(52) U.S. Cl. CPC H05K 7/20436; E21B 41/0007; H05K 7/209

(57) ABSTRACT

A subsea enclosure system is disclosed. In an embodiment, the subsea enclosure system includes an enclosure adapted to be deployed under water; a heat generating electric or electronic component arranged in the enclosure; and a non-fluid block including an electrically insulating, thermally conductive material. The non-fluid block is, on at least one surface, in direct contact with the heat generating electronic component and, on another surface, in contact with the inner surface of one or more walls of the pressure resistant enclosure, enabling the non-fluid transfer of heat from the electronic component to the wall of the enclosure when the subsea enclosure system is operating.

### PRIORITY STATEMENT

This application is the national phase under 35 U.S.C. §371 of PCT International Application No. PCT/EP2014/069870 which has an International filing date of Sep. 18, 2014, which designated the United States of America and which claims priority to European patent application number EP13185892.0 filed Sep. 25, 2013, the entire contents of which are hereby incorporated herein by reference.

### FIELD

An embodiment of the invention generally relates to subsea electronic components, particularly disposal of the heat generated by subsea electronic components inside of subsea canisters or enclosures.

### BACKGROUND

In subsea production facilities and subsea electronics more generally, disposal of heat generated during operation of an electronic component is a problem. Subsea circuits, electronics and power components can produce vast amounts of excessive heat during operation. Failure to efficiently dispose of this heat results in heightened temperatures of the environment surrounding the electronic component, further leading to reduced performance of the electronic component as well as shortened expected useful lifetime.

In subsea applications, the electronic component is typically housed in a canister or other enclosure, and the excessive heat it generates remains inside the canister until it is transported from the electronic component through the canister wall and into the surrounding seawater. Currently, the subsea canisters are filled with a fluid, either a gas or a liquid, separating the electronic component from the canister wall. However, as the fluid does not serve as an efficient medium for heat transport, the temperature of the fluid and thus of the environment surrounding the electronic component increases. This temperature increase is potentially damaging for the electronic component and reduces its useful life expectancy. Coping with more frequent maintenance and replacement of overheated electronic components is costly and time-consuming. A solution that avoids elevated temperatures inside the canister by efficiently disposing of heat generated by a subsea electronic component would therefore be beneficial.

For solving the above problem, solutions are known which make use of a heat sink for improving the heat conduction into the surrounding sea water. Although such solutions improve the cooling of a heat generating electronic component, the operating temperature still remains relatively high, and a further improvement of the heat transfer is desirable.

Active cooling systems employing fans, pumps and the like generally suffer from the drawback that they are complex and costly to implement. Further, they are prone to failure, in particular over the expected lifetime of such subsea system which can exceed 25 years. It is desirable to keep the system relatively simple and cost efficient. Also, it is desirable to provide a system with a relatively long lifetime and long service intervals.

### SUMMARY

Accordingly, there is a need to improve the cooling of an electronic component in a subsea enclosure.

The claims describe embodiments of the invention.

According to an embodiment of the invention, a subsea enclosure system is provided which comprises an enclosure adapted to be deployed under water; a heat generating electronic component arranged in the enclosure, the electronic component generating heat in operation; and a non-fluid block comprising at least a first layer of an electrically insulating, thermally conductive material, in particular a ceramic material. The non-fluid block is at at least one surface in direct contact with the heat generating electronic component and at another surface in direct contact with the inner surface of at least one wall of the enclosure, so as to enable the non-fluid transfer of heat from the heat generating electronic component to the at least one wall of the enclosure via the non-fluid block when the subsea enclosure system is deployed under water in an operating state.

It is to be understood that the features mentioned above and those yet to be explained below can be used not only in the respective combinations indicated, but also in other combinations or in isolation, without leaving the scope of the present invention.

### BRIEF DESCRIPTION OF THE DRAWINGS

The foregoing and other features and advantages of the invention will become further apparent from the following detailed description read in conjunction with the accompanying drawings. In the drawings, like reference numerals refer to like elements.

FIG. 1 is a schematic drawing showing a first embodiment of the subsea enclosure system.

FIG. 2 is a schematic drawing showing a second embodiment of the subsea enclosure system.

### DETAILED DESCRIPTION OF THE EXAMPLE EMBODIMENTS

According to an embodiment of the invention, a subsea enclosure system is provided which comprises an enclosure adapted to be deployed under water; a heat generating electronic component arranged in the enclosure, the electronic component generating heat in operation; and a non-fluid block comprising at least a first layer of an electrically insulating, thermally conductive material, in particular a ceramic material. The non-fluid block is at at least one surface in direct contact with the heat generating electronic component and at another surface in direct contact with the inner surface of at least one wall of the enclosure, so as to enable the non-fluid transfer of heat from the heat generating electronic component to the at least one wall of the enclosure via the non-fluid block when the subsea enclosure system is deployed under water in an operating state.

By such system, heat can be conducted efficiently through the non-fluid block to the enclosure wall without the need to conduct the heat through a liquid or gas which might fill the subsea enclosure. Accordingly, cooling of the electric or electronic component can be improved. Further, since the first layer is electrically insulating, discharges or short circuits through the enclosure wall, which can be made of metal, can be prevented. Even high voltage components may thus be cooled efficiently by heat conduction through non-fluid material.

In some embodiments, the non-fluid block includes the first layer, i.e. the non-fluid block may be made of the electrically insulating, thermally conductive material, in particular the ceramic material, and no further layers are provided. In other embodiments, the first layer only forms a part of the non-fluid block, and other parts thereof may include different materials, for example a second layer made of metal or the like may be provided.

The enclosure may be adapted to maintain a predetermined pressure inside the enclosure when the system is deployed under water.

In one embodiment of the invention, the enclosure may be a pressure resistant enclosure. A pressure resistant enclosure offers the advantage that the pressure inside the enclosure remains approximately atmospheric and may provide more ideal operating conditions for certain electronic components housed within the enclosure.

In one embodiment of the invention, the enclosure may be a pressure compensated enclosure adapted to allow the pressure within the enclosure to be balanced to the pressure outside of the enclosure, e.g. via a pressure compensator.

This embodiment of the invention may provide an enclosure with reduced wall thickness due to the lower differential pressure and may also provide more ideal operating conditions for certain electronic components housed within the enclosure. Pressure balancing may occur via a pressure compensator mounted to the enclosure, for example a bellows, piston or membrane type of pressure compensator.

In one embodiment of the invention, the enclosure may be a canister. A canister is advantageous in that it provides a physical barrier separating the outside liquid environment from the electronic component housed inside the canister. Moreover, it provides the surface or surfaces across which heat generated by the electronic component may be transferred to the outside liquid environment.

In one embodiment of the invention, the heat generating component may be an electronic component, in particular a power electronic component. In particular, the electronic component may be a power electronic component of a subsea variable speed drive or adjustable speed drive. The component may for example be a diode, a thyristor, an IGBT or the like.

In one embodiment of the invention, the contact between the non-fluid block and the electronic component as well as the contact between the non-fluid block and an inner surface of the pressure resistant enclosure may be achieved mechanically, such as with the use of etched grooves, nails, fasteners or hooks.

The contact may also be achieved through an adhesive such as thermal glue. Both the mechanical connection as well as a connection achieved with adhesive offer the advantage that the non-fluid block remains in a fixed position relative to the electronic component and the pressure resistant enclosure.

Thermal glue may for example be a gel or paste that is provided at the interface between the non-fluid block and the component and/or at the interface between the non-fluid block and the enclosure wall.

According to another embodiment of the invention, the electrically insulating, thermally conductive material features relatively high thermal conductivity, for example at least 50 Wm−1K−1. Preferably, the thermal conductivity of the material is at least 70 Wm−1K−1, more preferably at least 100 Wm−1K−1.

Materials that are considered to have relatively high thermal conductivity and that may be used with embodiments of the invention include ceramic materials, and in particular Aluminum Nitride, Boron Nitride and Aluminum Oxide. In other embodiments, different types of material may be used, e.g. materials other than ceramic materials.

According to another embodiment of the invention, the non-fluid block may be comprised of or may consist of two or more layers. The first layer, adjacent to the heat generating electronic component, may be comprised of or may consist of electrically insulating, thermally conductive material, while the second layer, adjacent to one wall of the enclosure, may be comprised of or may consist of thermal transportation material. Examples of electrically insulating, thermally conductive materials of which the first layer may be comprised or consist include Aluminum Nitride, Boron Nitride and Aluminum Oxide, either alone or in combination with other materials. Examples of thermal transportation materials of which the second layer may be comprised or may consist of steel, aluminum, copper and other materials with similar thermal conductivity. Similarly, the thermal transportation materials may be found either alone or in combination with other materials in the second layer.

The non-fluid block may be a solid block including of the one, two or more layers. One layer may be a flexible or resilient layer. As an example, the above-mentioned second layer made of a thermal transportation material may be a metal layer having a flexible or resilient structure. This may be achieved by the structural configuration of the layer, which may e.g. include lamellae or a spring-type structure.

The heat generating electronic component may be press fitted to a wall of the enclosure. The electric or electronic component may for example be part of a converter unit, in particular a power cell, e.g. of a VSD, which converter unit or power cell is press fitted against the inner wall of the enclosure for mounting it thereto. Thereby, the flexible or resilient layer may be compressed, so as to facilitate the press fitting against the enclosure wall, and further improving the thermal conduction of heat away from the component towards the enclosure wall via the non-fluid block, e.g. via the first ceramic layer and a second flexible or resilient metal layer.

The enclosure may be a cylindrical canister allowing such press-fitting, e.g. to an inner cylindrical wall.

In other embodiments, the electric or electronic component may for example be bolted to the non-fluid block, which may be bolted against the wall of the enclosure, in particular without using such flexible or resilient layer.

It is to be understood that the features mentioned above and those yet to be explained below can be used not only in the respective combinations indicated, but also in other combinations or in isolation, without leaving the scope of the present invention.

In subsea applications, heat generated from electronic components is transported by natural convection from the electronic component 1 into the surrounding fluid within the canister. The heat is then transferred across the canister wall 4 into the seawater. As subsea electronic components often carry high currents and high voltages, positioning them directly adjacent to the canister wall for cooling by the cold seawater surrounding the canister may result in a short circuit and is thus not a feasible solution. Consequently, a certain insulation distance is generally required. Rather than a solution based on convective transfer of heat, the solution and invention described herein relies on the conductive transfer of heat through a non-fluid block 2 comprised of a material, in particular a ceramic material, that is also electrically insulating and provides a more efficient and effective method of heat disposal.

Thermal conductivity (k) is the ability of a material to transport thermal energy due to temperature gradient. Examples of materials with high thermal conductivity that are also electrically insulating and that can be used in embodiments of the invention include Aluminum Nitride, Boron Nitride and Aluminum Oxide.

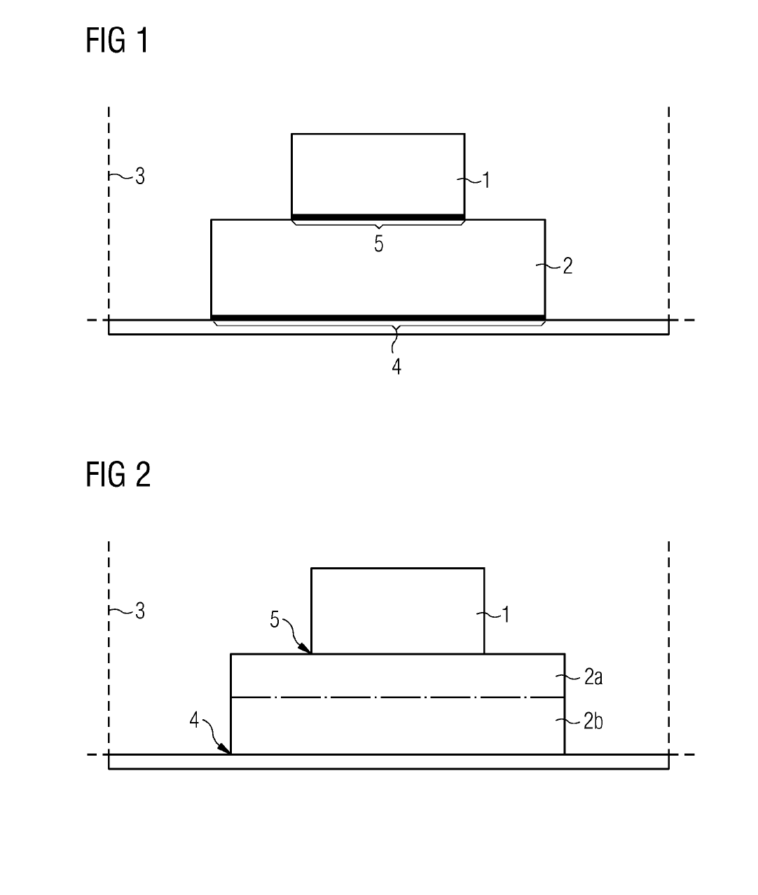

As shown in FIG. 1, in one embodiment of the invention a subsea enclosure system is comprised of: an enclosure 3 adapted to maintain a predetermined pressure inside the enclosure when the system is deployed under water; a heat generating electronic component 1 arranged in the enclosure, the electronic component generating heat in operation; a non-fluid block 2 comprised of an electrically insulating, thermally conductive material which is at at least one surface 5 in direct contact with the heat generating electronic component and at another surface 4 in direct contact with the inner surface of at least one wall of the pressure resistant enclosure, so as to enable the non-fluid transfer of heat from the heat generating electronic component to the at least one wall of the enclosure when the subsea enclosure system is deployed under water in an operating state.

As shown in FIG. 2, the non-fluid block described in the embodiment above in another embodiment may be comprised of two or more layers, one of which is comprised of an electrically insulating, thermally conductive material 2a, and a second layer comprised of thermal transportation material 2b. The thermal transportation material may be made of a metal, such as steel, aluminum or copper. In this second embodiment, the non-fluid block is positioned such that the layer of electrically insulating, thermally conductive material is adjacent to the heat generating electronic component.

The enclosure may be a pressure resistant enclosure, meaning that the pressure inside the enclosure is relatively constant and independent of deployment depth. The enclosure may thus have relatively thick wall in order to withstand large differential pressures, yet conventional electronic components can be used inside such enclosure. In other embodiments, the enclosure may be a pressure compensated enclosure in which the pressure inside the enclosure is balanced or equalized to the pressure prevailing outside the enclosure, e.g. in the ambient sea water. This can be achieved by providing the enclosure with a pressure compensator and filling the enclosure with a liquid, in particular a dielectric liquid. Pressure tolerant electronic components can be used in such enclosure. The pressure compensated enclosure has the advantage that it only needs to withstand relatively small differential pressures, it may thus be provided with relatively thin walls resulting in a compact and light weight enclosure.

In the above embodiments of the invention, the respective direct contacts between the non-fluid block and the heat generating electronic component and the inner surface of at least one wall of the pressure resistant enclosure can be achieved either through mechanical connection or with use of thermal glue.

In the above embodiments, the thermal conductivity of the electrically insulating, thermally conductive non-fluid material is at least 50 Wm−1K−1. Preferably, the thermal conductivity of the material is at least 70 Wm−1K−1, more preferably at least 100 Wm−1K−1. Examples of materials in this range of thermal conductivity that could be used in the embodiments include Aluminum Nitride, Boron Nitride or Aluminum Oxide either alone or in combination with other materials.

1. A subsea enclosure system, comprising:
an enclosure adapted to be deployed under water;
a heat generating electric or electronic component arranged in the enclosure, the heat generating electric or electronic component being configured to generate heat in operation;
a non-fluid block including at least a first layer of an electrically insulating, thermally conductive ceramic material, wherein the non-fluid block is, on at least one surface, in direct contact with the heat generating electric or electronic component and, on another surface, in direct contact with an inner surface of at least one wall of the enclosure, so as to enable the non-fluid transfer of heat from the heat generating electric or electronic component to the at least one wall of the enclosure via the non-fluid block when the subsea enclosure system is deployed under water in an operating state.

2. The invention of claim 1, wherein the enclosure is a pressure compensated enclosure adapted to allow balancing of a pressure inside the enclosure in relation to a pressure outside of the enclosure.

3. The invention of claim 1, wherein the enclosure is a pressure resistant enclosure adapted to maintain a pressure below 5 bar.

4. The invention of claim 1, wherein the non-fluid block is comprised of two or more layers including the first layer, and including a second layer comprised of thermal transportation material, and wherein the non-fluid block is positioned such that the first layer of electrically insulating, thermally conductive ceramic material is adjacent to the heat generating electric or electronic component.

5. The invention of claim 4, wherein the second layer of thermal transportation material includes or is composed of a metal.

6. The invention of claim 4, wherein the second layer of thermal transportation material includes or consists of aluminum or copper.

7. The invention of claim 4, wherein the second layer of thermal transportation material is a metal layer having a resilient or flexible structure.

8. The invention of claim 1, wherein the direct contacts are achieved through mechanical connection.

9. The invention of claim 1, wherein the direct contacts are achieved through etched grooves, nails, fasteners or hooks.

10. The invention of claim 1, wherein the direct contacts are achieved through an adhesive.

11. The invention of claim 1, wherein the direct contacts are achieved using thermal glue.

12. The invention of claim 1, wherein the electrically insulating, thermally conductive ceramic material has a thermal conductivity of at least 50 Wm⁻¹K⁻¹.

13. The invention of claim 1, wherein the electrically insulating, thermally conductive ceramic material has a thermal conductivity of at least 70 Wm⁻¹K⁻¹.

14. The invention of claim 1, wherein the electrically insulating, thermally conductive ceramic material has a thermal conductivity of at least 100 Wm⁻¹K⁻¹.

15. The invention of claim 1, wherein the electrically insulating, thermally conductive ceramic material is composed of or consists of Aluminum nitride, Boron Nitride or Aluminum Oxide either alone or in combination with other materials.

16. The invention of claim 1, wherein the enclosure is a pressure resistant enclosure adapted to maintain substantially atmospheric pressure inside the enclosure.

17. The invention of claim 5, wherein the second layer of thermal transportation material includes or consists of aluminum or copper.

18. The invention of claim 7, wherein the second layer of thermal transportation material is an aluminum layer.

19. The invention of claim 2, wherein the electrically insulating, thermally conductive ceramic material is composed of or consists of Aluminum nitride, Boron Nitride or Aluminum Oxide either alone or in combination with other materials.

20. The invention of claim 4, wherein the electrically insulating, thermally conductive ceramic material is composed of or consists of Aluminum nitride, Boron Nitride or Aluminum Oxide either alone or in combination with other materials.
